(19) United States
(12) Patent Application Publication
(10) Pub. No.: US 2004/0150013 A1
(43) Pub. Date: Aug. 5, 2004

(54) Semiconductor device

(75) Inventor: Takashi Ipposhi, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., TOKYO (JP)

(21) Appl. No.: 10/623,557

(22) Filed: Jul. 22, 2003

(30) Foreign Application Priority Data
Jan. 22, 2003 (JP) 2003-013062

(51) Int. Cl. H01L 33/00

(52) U.S. Cl. 257/288

(57) ABSTRACT

A semiconductor device on a semiconductor substrate, which provides for effective use of characteristics of the semiconductor substrate, is provided. A P-channel MOS transistor is provided on an SOI substrate which is formed by aligning an SOI layer (3) having a <100> crystal direction and a supporting substrate (1) having a <110> crystal direction so as to allow the respective crystal directions to be parallel to each other. Then, a portion of the supporting substrate 1 is removed to form a hollow portion (HL1), to produce a strain in a channel region. Specifically, as a result of formation of the hollow portion (HL1) by removing a portion of the supporting substrate (1), a tensile stress is caused on an oxide film layer (2) and an SOI layer (3) located above the hollow portion (HL1). This results in production of a strain in the SOI layer (3) which includes the channel region of the MOS transistor, thereby to increase carrier mobility of a channel.

### BACKGROUND OF THE INVENTION

1. Field of the Invention

The present invention relates to a semiconductor device provided on a semiconductor substrate.

2. Description of the Background Art

A P-channel MOS (Metal Oxide Semiconductor) transistor provided on an SOI (Silicon-On-Insulator or Semiconductor-On-Insulator) substrate is one example of a conventional semiconductor device.

A typical SOI substrate is formed of a supporting substrate such as a silicon substrate, an oxide film layer and an SOI layer which are sequentially deposited in the order noted. A typical P-channel MOS transistor includes a gate electrode, a gate insulating film and a P-type source/drain active layer.

In providing a P-channel MOS transistor on an SOI substrate, typically, a stacked structure composed of a gate electrode and a gate insulating film of the P-channel MOS transistor is provided on a surface of an SOI layer of the SOI substrate while a source/drain active layer of the P-channel MOS transistor is provided in the SOI layer so as to be located on opposite sides of a portion of the SOI layer under the gate electrode.

Meanwhile, in accordance with conventional practices, a semiconductor device has generally been configured such that a direction of a channel to be formed between a source and a drain of a MOS transistor (i.e., a direction in which a channel length extends, which will be hereinafter referred to as a “channel direction”) can be parallel to a <110> crystal direction of a semiconductor wafer.

On the other hand, however, it has been found that configuring a semiconductor device such that a channel direction can be parallel to a <100> crystal direction, not a <110> crystal direction, would result in change of transistor characteristics. More specifically, it has been found that the configuration which allows a channel direction to be parallel to a <100> crystal direction results in approximately 15%-improvement of current drive capability of a P-channel MOS transistor, and in addition, reduces a short channel effect (see Japanese Patent Application Laid-Open No. 2002-134374).

A channel direction parallel to a <100> crystal direction provides for higher hole mobility than a channel direction parallel to a <110> crystal direction. For this reason, current drive capability of a P-channel MOS transistor is improved by utilizing the configuration which allows a channel direction to be parallel to a <100> crystal direction. Also, a channel direction parallel to a <100> crystal direction provides for lower diffusion coefficient of boron than a channel direction parallel to a <110> crystal direction. For this reason, a short channel effect is reduced by utilizing the foregoing configuration.

Also in providing a P-channel MOS transistor on a SOI substrate to form a semiconductor device, configuring the semiconductor device such that a channel direction can be parallel to a <100> crystal direction of an SOI layer of the SOI substrate would produce advantages. To this end, it is preferable to employ an SOI substrate which is formed by aligning an SOI layer in a surface region thereof having a <100> crystal direction and a supporting substrate having a <110> crystal direction so as to allow the respective crystal directions to be parallel to each other, and to provide the P-channel MOS transistor and the like on a surface of the SOI substrate, for example.

When a wafer has a (100) crystal direction, a cleavage plane of the wafer is a {110} crystal plane. As such, by bonding a wafer serving as an SOI layer having a <100> crystal direction and a wafer serving as a supporting substrate having a <110> crystal direction to each other while aligning the SOI layer and the supporting substrate so as to allow the respective crystal directions to be parallel to each other, it is possible to split a new wafer formed of the two bonded wafers along a cleavage plane of the wafer serving as the supporting substrate which forms a greater part of the new wafer in thickness, during a cleaving process in research and/or study. This advantageously makes it possible to expose a section having a <110> crystal direction in the supporting substrate while exposing a section having a <100> crystal direction in the SOI layer.

A technique for aligning substances having respective crystal directions so as to allow the respective crystal directions to be parallel to each other, e.g., aligning the SOI layer having a <100> crystal direction and the supporting substrate having a <110> crystal direction so as to allow the respective crystal directions to be parallel to each other as noted above, is described in Japanese Patent Application Laid-Open Nos. 2002-134374 (also referred to above) and 7-335511.

Further, the following references can be mentioned herein as prior art references for the present invention: Y. Hirano et al., “Bulk-Layout-Compatible 0.18 μm SOI-CMOS Technology Using Body-Fixed Partial Trench Isolation (PTI)”, (U.S.A.), IEEE 1999 SOI conf., pp. 131-132; S. Maeda et al., “Suppression of Delay Time Instability on Frequency using Field Shield Isolation Technology for Deep Sub-Micron SOI Circuits”, (U.S.A.), IEDM, 1996, pp. 129-132; and L.-J. Huang et al., “Carrier Mobility Enhancement in Strained Si-On-Insulator Fabricated by Wafer Bonding”, (U.S.A.), 2001 Symposium on VLSI Technology, pp. 57-58 (hereinafter, referred to as “Huang reference”).

As described above, an SOI substrate which is formed by aligning an SOI layer having a <100> crystal direction and a supporting substrate having a <110> crystal direction so as to allow the respective crystal directions to be parallel to each other is suitable for use in forming a P-channel MOS transistor in view of its effect of improving current drive capability of the P-MOS transistor. However, current drive capability of a P-channel MOS transistor is susceptible to further improvement.

### SUMMARY OF THE INVENTION

It is an object of the present invention to obtain a semiconductor device which provides for further improvement in current drive capability of a MOS transistor provided on a semiconductor substrate.

According to a first aspect of the present invention, a semiconductor device includes an SOI substrate and a MIS (Metal Insulator Semiconductor) transistor. The SOI substrate includes a supporting substrate, an oxide film layer and an SOI (Semiconductor-On-Insulator) layer which are sequentially deposited. The MIS transistor includes a gate insulating film formed on the SOI layer, a gate electrode formed on the gate insulating film and a source/drain active layer formed in the SOI layer so as to be adjacent to a portion under the gate electrode. At least a portion of the supporting substrate which is located under the MIS transistor is removed, to form a hollow portion.

In the semiconductor device, at least a portion of the supporting substrate of the SOI substrate which is located under the MIS transistor is removed. This makes it possible to produce a strain in the SOI layer including a channel region where a channel of the MIS transistor is to be formed, thereby to increase carrier mobility of the channel.

According to a second aspect of the present invention, a semiconductor device includes an SOI substrate, a MIS (Metal Insulator Semiconductor) transistor, an interlayer insulating film and a supporting substrate. The SOI substrate includes an oxide film layer serving as a bottom of the semiconductor device and an SOI (Semiconductor-On-Insulator) layer which are sequentially deposited. The MIS transistor includes a gate insulating film formed on the SOI layer, a gate electrode formed on the gate insulating film and a source/drain active layer formed in the SOI layer so as to be adjacent to a portion under the gate electrode. The interlayer insulating film covers the MIS transistor. The supporting substrate is bonded to the interlayer insulating film.

There is provided no supporting substrate under the oxide film layer, and the oxide film layer serves as a bottom of the semiconductor device. Hence, heat generated in the MIS transistor and in the vicinity thereof can be effectively dissipated. Further, a problem associated with structural strength is unlikely to occur because of inclusion of the supporting substrate bonded to the interlayer insulating film.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a top view of a semiconductor device according to a first preferred embodiment.

FIG. 2 is a sectional view of the semiconductor device according to the first preferred embodiment.

FIG. 3 is a top view of a semiconductor device according to a modification of the first preferred embodiment.

FIG. 4 is a sectional view of the semiconductor device according to the modification of the first preferred embodiment.

FIG. 5 is a top view for illustrating a process for manufacturing the semiconductor device according to the modification of the first preferred embodiment.

FIG. 6 is a sectional view for illustrating the process for manufacturing the semiconductor device according to the modification of the first preferred embodiment.

FIG. 7 is another top view for illustrating another process for manufacturing the semiconductor device according to the modification of the first preferred embodiment.

FIG. 8 is another sectional view for illustrating another process for manufacturing the semiconductor device according to the modification of the first preferred embodiment.

FIG. 9 is a top view of the semiconductor device according to another modification of the first preferred embodiment.

FIG. 10 is a sectional view of a semiconductor device according to a second preferred embodiment.

FIG. 11 is a sectional view of a semiconductor device according to a third preferred embodiment.

FIGS. 12, 13 and 14 are sectional views of a semiconductor device according to a fourth preferred embodiment.

### DESCRIPTION OF THE PREFERRED EMBODIMENTS

### Preferred Embodiments

First Preferred Embodiment

A first preferred embodiment of the present invention will describe a semiconductor device in which a P-channel MOS transistor is provided on an SOI substrate which is formed by aligning an SOI layer having a <100> crystal direction and a supporting substrate having a <110> crystal direction so as to allow the respective crystal directions to be parallel to each other, and a portion of the supporting substrate located under the P-channel MOS transistor is removed thereby to produce a strain in a channel region where a channel is to be formed during operation.

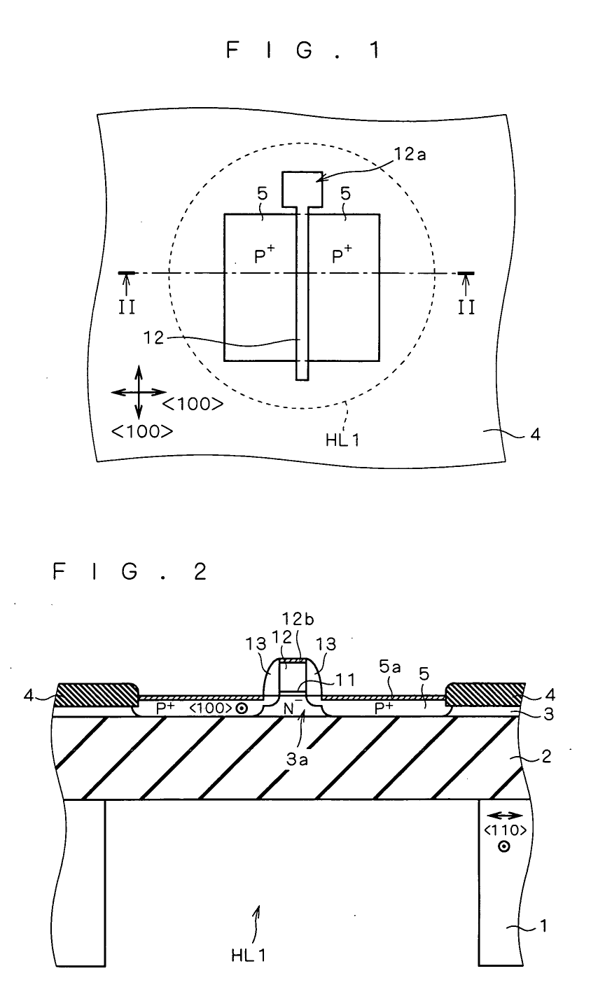

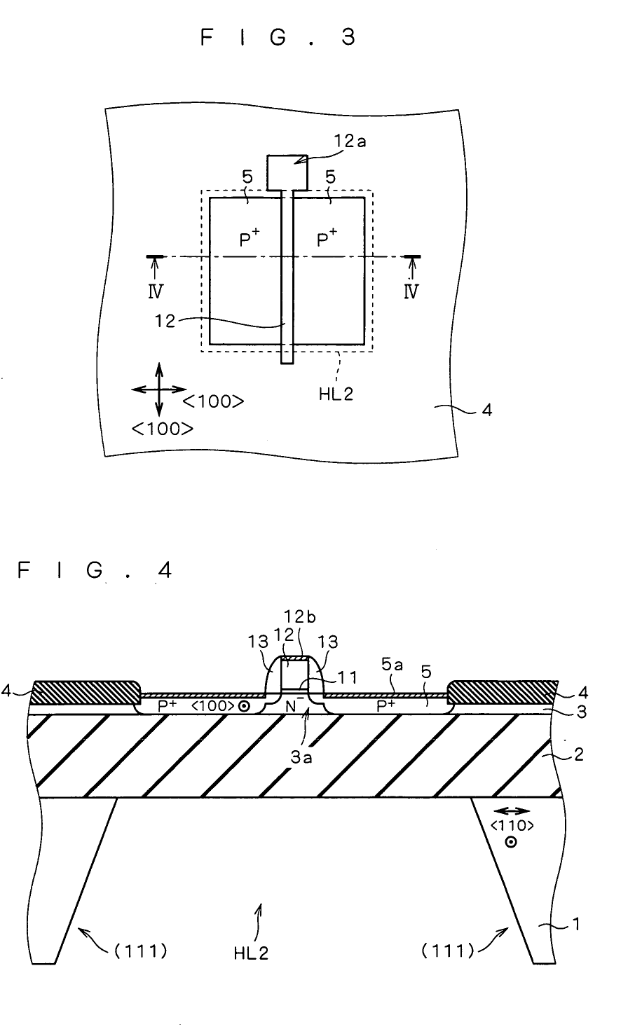

FIGS. 1 and 2 illustrate the semiconductor device according to the first preferred embodiment. It is noted that FIG. 2 is a sectional view taken along a line II-II in FIG. 1.

The semiconductor device according to the first preferred embodiment includes a P-channel MOS transistor provided on a surface of an SOI substrate. The SOI substrate is formed of a supporting substrate 1 such as a silicon substrate, an oxide film layer 2 and an SOI layer 3 such as a silicon layer, which are sequentially deposited in the order noted. The P-channel MOS transistor includes a gate electrode 12, a gate insulating film 11 and a P-type source/drain active layer 5.

The gate electrode 12 and the gate insulating film 11 compose a stacked structure which is provided on a surface of the SOI layer 3. The P-type source/drain active layer 5 is provided in the SOI layer 3 so as to be located adjacent to the gate electrode 12 in plan view. A periphery of the P-type source/drain active layer 5 is defined by an isolation region 4 which functions to provide partial isolation.

Further, a sidewall insulating film 13 is formed on each side face of the gate electrode 12 and the gate insulating film 11. Moreover, silicided regions 12b and 5a are formed in respective surface regions of the gate electrode 12 and the source/drain active layer 5. The gate electrode 12 is non-uniform in width thereof. Specifically, a portion of the gate electrode 12 which is located adjacent to the source/drain active layer 5 in plan view is elongated in order to reduce a gate length, while an extraction portion 12a of the gate electrode 12 which is to be connected with a contact plug (not illustrated) is relatively wide. Furthermore, an N-type body layer 3a having a relatively low concentration (N⁻) is formed in a portion of the SOI layer 3 which is located under the gate electrode 12.

As illustrated in FIGS. 1 and 2, a portion of the supporting substrate 1 which is located under the MOS transistor is removed, to form a hollow portion HL1 in the semiconductor substrate.

In accordance with the first preferred embodiment, a portion of the supporting substrate 1 of the SOI substrate which is located under the P-channel MOS transistor is removed to a hollow portion, as described above. Because of the removal of the portion of the supporting substrate 1 and formation of the hollow portion, a tensile stress is caused on the oxide film layer 2 and the SOI layer 3 located above the hollow portion. As a result, it is possible to produce a strain in the SOI layer 3 including a channel region of the MOS transistor. This provides for increase in carrier mobility in a channel.

Below, explanation about how production of a strain in the SOI layer increases carrier mobility in a channel will be made.

First, assume that a MOS transistor has a structure in which an SOI layer includes a strained silicon channel layer having an increased lattice constant as compared to silicon in a normal state, in a surface region thereof (i.e., a channel region where a channel is to be formed), and also includes a silicon germanium layer having a greater lattice constant than that of silicon, in the other region adjacent to the channel region thereof (hereinafter, referred to as a “nearby region”) (see Huang reference). The foregoing structure may be called a strained channel structure.

The strained channel structure is formed by epitaxially growing a silicon layer on the nearby region having a greater lattice constant than that of silicon. Accordingly, the silicon layer in the surface region of the SOI layer has a lattice constant substantially identical to that of the nearby region, under the influence of a lattice structure of the nearby region. That is, the silicon layer has a lattice constant greater than that of silicon in a normal state. As a result, the silicon layer in the surface region of the SOI layer is under a tensile stress. This results in increase in carrier mobility in the channel, thereby to obtain a MOS transistor with improved characteristics.

In accordance with the first preferred embodiment, a portion of the supporting substrate 1 is removed to form a hollow portion, so that a tensile stress is caused on the oxide film layer 2 and the SOI layer 3 located above the hollow portion. In this manner, the same effects as produced in a MOS transistor having the strained channel structure can be obtained in the semiconductor device according to the first preferred embodiment.

Further, in accordance with the first preferred embodiment, the supporting substrate 1 and the SOI layer 3 of the SOI substrate have crystal directions different from each other. Accordingly, the supporting substrate 1 and the SOI layer 3 have different cleavage planes. This prevents the SOI substrate from being easily split.

Moreover, transistor characteristics depend on a stress. For this reason, it is important to control a stress. This particularly applies to the first preferred embodiment, in which a portion of the supporting substrate 1 is removed to form a hollow portion for the purpose of causing a tensile stress on the oxide film layer 2 and the SOI layer 3 located above the hollow portion. In the semiconductor device according to the first preferred embodiment, a stress must be controlled with higher accuracy. In this regard, by utilizing the SOI substrate according to the first preferred embodiment, it is possible to not only improve current drive capability of the P-channel MOS transistor, but also suppress an imponderable stress possibly caused during manufacture, thereby to achieve improved control of a stress.

The structure illustrated in FIGS. 1 and 2 can be easily manufactured. For example, a photoresist is formed on one of opposite surfaces of the supporting substrate 1 which is farther from the oxide film layer 2, and is patterned so as to serve as a mask used in etching for forming the hollow portion HL1. Then, etching is carried out using the mask, and thereafter the photoresist is removed. In this manner, the structure illustrated in FIGS. 1 and 2 can be obtained.

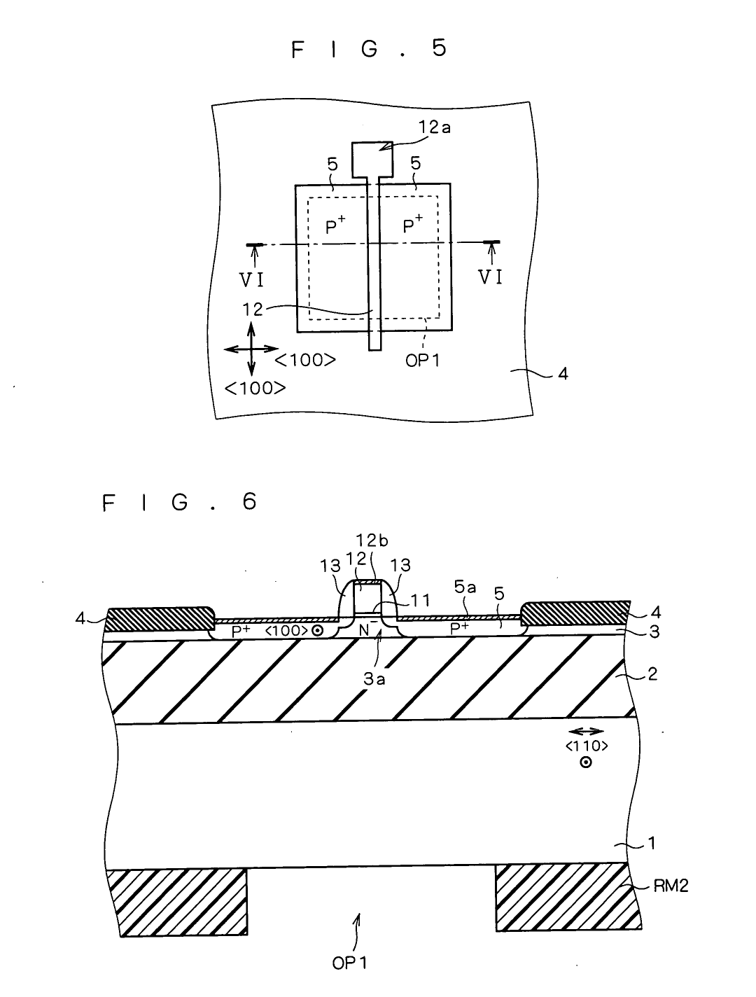

FIGS. 3 and 4 illustrate a modification of the structure illustrated in FIGS. 1 and 2. FIG. 4 is a sectional view taken along a line IV-IV in FIG. 3. In accordance with this modification, a hollow portion HL2 which, in plan view, has a shape of a rectangle substantially identical in size to the source/drain active layer 5 is formed in a portion of the supporting substrate 1 located just under the source/drain active layer 5 of the P-channel MOS transistor. Each of four end faces of the supporting substrate 1 which surround the hollow portion HL2 and thus are exposed in the hollow portion HL2 is a (111) plane.

A (111) plane is parallel to a <110> crystal direction. Accordingly, by performing etching which exposes a (111) plane, it is possible to form a hollow portion having sides parallel to a <110> crystal direction of the supporting substrate 1, in the supporting substrate 1. As a result, the portion to be removed in the supporting substrate 1 can be made rectangular in plan view. This makes it possible to minimize a size of the portion to be removed in the supporting substrate, depending on a size of the MOS transistor.

Below, processes for the etching which exposes a (111) plane will be explained.

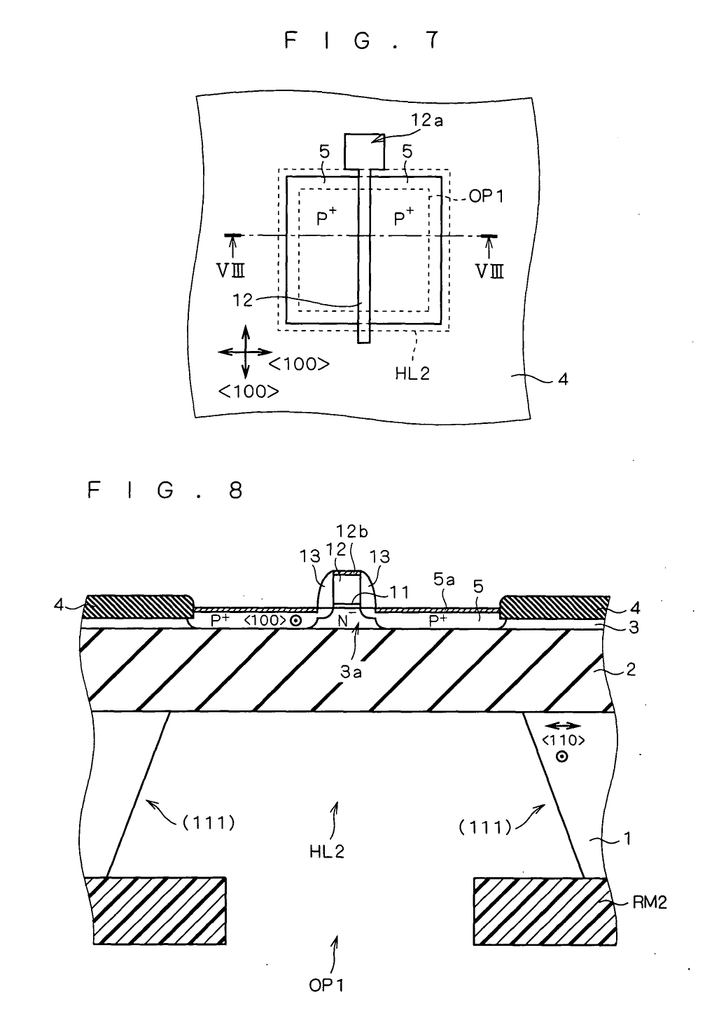

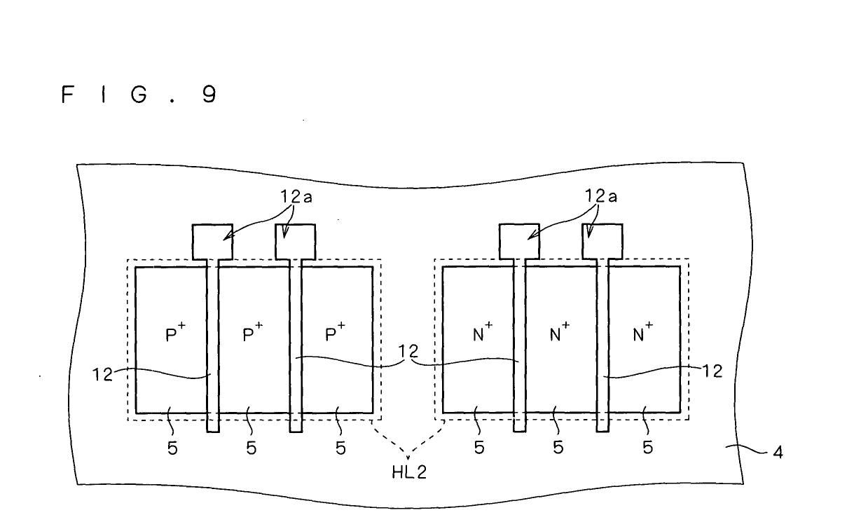

As illustrated in FIGS. 5 and 6, first, a photoresist RM2 is formed on one of opposite surfaces of the supporting substrate 1 which is farther from the oxide film layer 2, so as to be located just under the MOS transistor. Then, an opening OP1 having an opening area smaller than that of the hollow portion HL2 is formed in the photoresist RM2. It is additionally noted that FIG. 6 is a sectional view taken along a line VI-VI in FIG. 5.

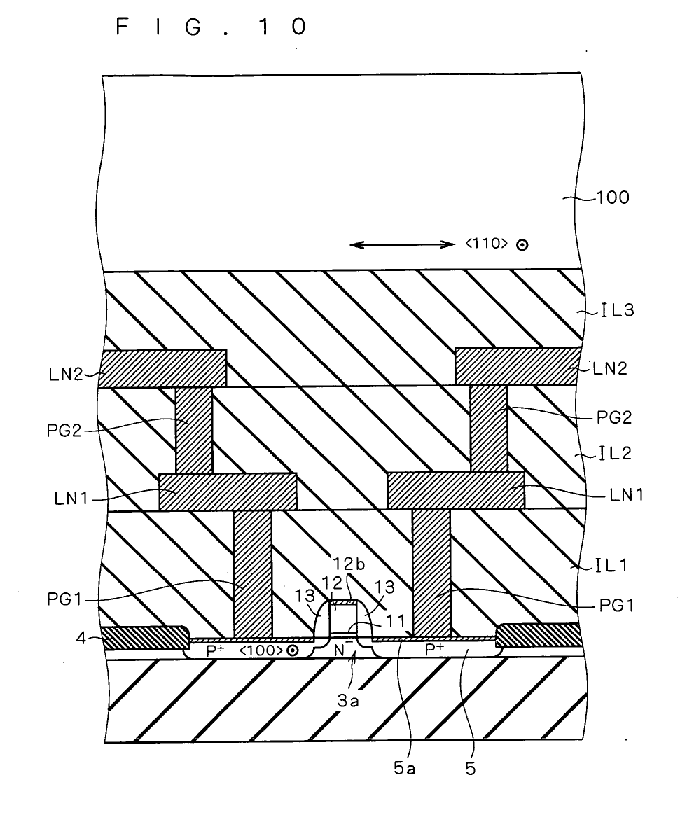

Next, wet etching is performed using a strong alkali solution such as a solution of potassium hydroxide. As a result, the hollow portion HL2 defined by the end faces of the supporting substrate 1, each of which is a (111) plane, is formed in the supporting substrate 1, as illustrated in FIGS. 7 and 8. A silicon oxide film is hardly etched by a solution of potassium hydroxide. Hence, the oxide film layer 2 functions as an etch stop. It is additionally noted that FIG. 8 is a sectional view taken along a line VIII-VIII in FIG. 7.

Thereafter, the photoresist RM2 is removed, thereby to obtain the structure illustrated in FIGS. 3 and 4.

For the strong alkali solution used for wet etching, a solution of sodium hydroxide, a solution of tetramethyl ammonium hydroxide or the like, as well as a solution of potassium hydroxide as cited above, may be employed.

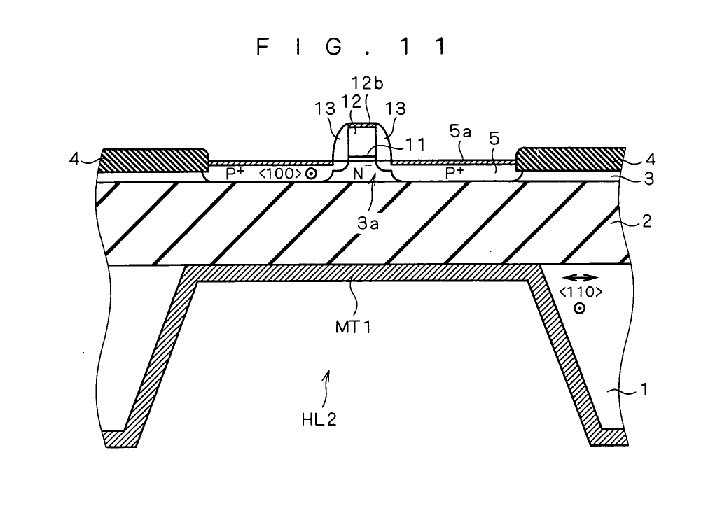

FIG. 9 illustrates an arrangement including a plurality of MOS transistors, in which case every two adjacent ones of the plurality of MOS transistors share the source/drain active layer 5. Also in this case, the hollow portion HL2 can be formed in the supporting substrate 1. The hollow portion HL2 is formed so as to extend over the source/drain active layers 5 each shared by every two adjacent ones of the plurality of the MOS transistors and the source/drain active layers 5 at opposite ends.

Second Preferred Embodiment

A second preferred embodiment is a modification of the first preferred embodiment. A semiconductor device according to the second preferred embodiment differs from the semiconductor device according to the first preferred embodiment in that the supporting substrate 1 is not included, and instead, interlayer insulating films provided on the MOS transistor and another supporting substrate bonded to the interlayer insulating films are included.

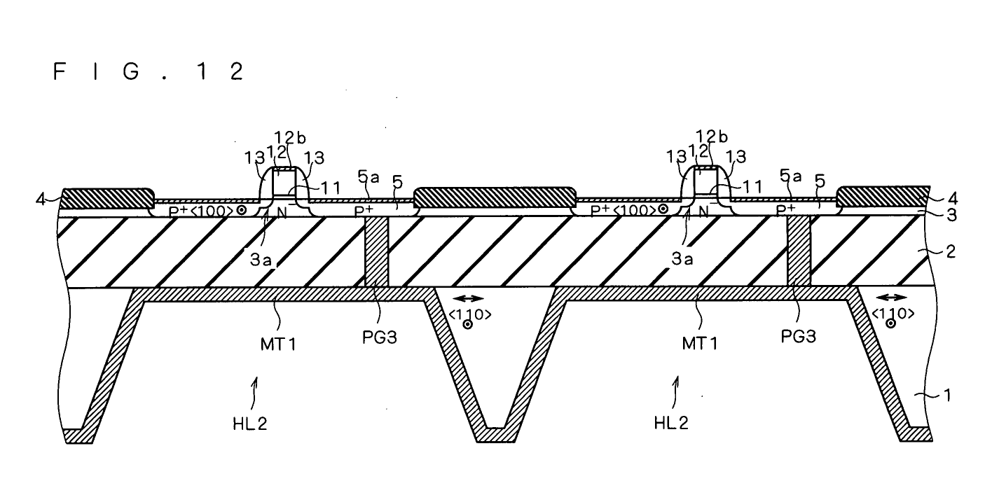

FIG. 10 illustrates the semiconductor device according to the second preferred embodiment. The semiconductor device according to the second preferred embodiment does not include the supporting substrate 1. Accordingly, the oxide film layer 2 serves as a bottom of the semiconductor device. The semiconductor device according to the second preferred embodiment includes first, second and third interlayer insulating films IL1, IL2 and IL3 covering the MOS transistor provided on the SOI layer 3.

Further, a second-level interconnect LN1 and a third-level interconnect LN2 are formed in the second and third interlayer insulating films IL2 and IL3, respectively. Moreover, a contact plug PG1 is provided to connect the second-level interconnect LN1 and the source/drain active layer 5 to each other, and a contact plug PG2 is provided to connect the third-level interconnect LN2 and the second-level interconnect LN1 to each other.

Furthermore, a supporting substrate 100, different from the supporting substrate 1 in the structure of the first preferred embodiment, is bonded to a surface of the uppermost interlayer insulating film, i.e., the third interlayer insulating film IL3. The supporting substrate 100 is bonded to the third interlayer insulating film IL3 while aligning the supporting substrate 100 having a <110> crystal direction with the SOI layer 3 having a <100> crystal so as to allow the respective crystal directions to be parallel to each other in the same manner as the supporting substrate 1 described in the first preferred embodiment. For the supporting substrate 100, a silicon substrate can be employed. However, suitable materials for the supporting substrate 100 are not limited to a semiconductor. Any substrate having a function of supporting, such as a glass substrate or a plastic substrate, for example, can be employed as the supporting substrate 100.

According to the second preferred embodiment, the supporting substrate 1 is temporarily provided during manufacture, in order to support elements which are being manufactured. The supporting substrate 1 is removed by etching, CMP (Chemical Mechanical Polishing) or the like, after the supporting substrate 100 is bonded.

Since the supporting substrate 1 is completely removed in the semiconductor device as a final structure according to the second preferred embodiment, heat generated in the MOS transistor and in the vicinity thereof can be effectively dissipated. Further, a problem associated with strength of the structure is unlikely to occur because of inclusion of the supporting substrate 100 which ensures adequate structural strength.

Third Preferred Embodiment

A third preferred embodiment is another modification of the first preferred embodiment. A semiconductor device according to the third preferred embodiment is different from the semiconductor device according to the first preferred embodiment in that a metal film is further provided, which covers the surface of the supporting substrate 1 including the end faces thereof exposed in the hollow portion HL1 or HL2.

FIG. 11 illustrates features of the third preferred embodiment by using the structure illustrated in FIG. 4, as one example. As illustrated in FIG. 11, in accordance with the third preferred embodiment, a metal film MT1 made of Au, Al, W, Cu or the like is formed by vacuum deposition or the like, on one of opposite surfaces of the supporting substrate 1 which is farther from the oxide film layer 2, as well as on the end faces of the supporting substrate 1 and a portion of the oxide film layer 2 which are exposed in the hollow portion HL2.

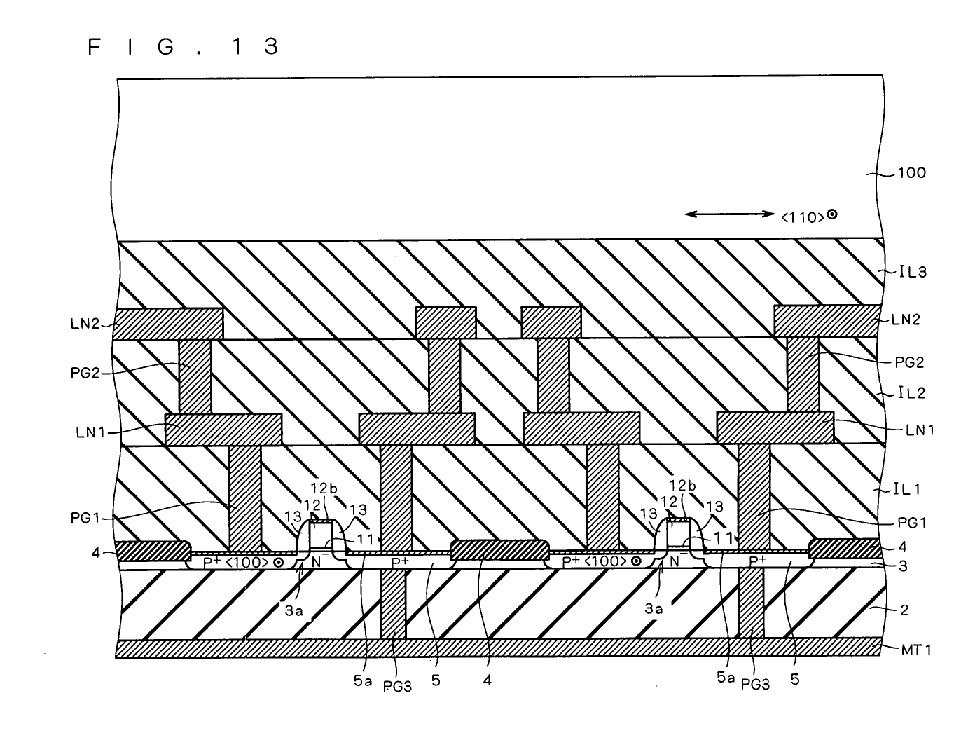

As a result of formation of the metal film MT1, it is possible to obtain a semiconductor device in which heat generated in the MOS transistor and in the vicinity thereof can be effectively dissipated. Also, if the metal film MT1 is formed at a high temperature of several hundred degrees, it results in greater shrinkage of the metal film MT1 as compared to the oxide film layer 2 and the SOI layer 3 when the temperature of the metal film MT1 becomes equal to a room temperature, because the metal film MT1 has a higher coefficient of thermal expansion than that of the oxide film layer 2 or the SOI layer 3. This ensures the effect of producing a strain in the SOI layer 3, thereby to increase carrier mobility in a channel. Additionally, although the metal film MT1 is illustrated as a relatively thin film in FIG. 11, the present invention should not be limited to such illustration. The thickness of the metal film MT1 may be larger than that of the oxide film layer 2. That is also true for FIGS. 12, 13 and 14.

Fourth Preferred Embodiment

A fourth preferred embodiment is a modification of the third preferred embodiment. A semiconductor device according to the fourth preferred embodiment is substantially identical to the semiconductor device according to the third embodiment except that the metal film MT1 on one of opposite surfaces of the supporting substrate 1 which is farther from the oxide film layer 2 is electrically connected to a part of the source/drain active layer 5 of the SOI layer 3.

FIG. 12 illustrates the semiconductor device according to the fourth preferred embodiment. Specifically, FIG. 12 illustrates two MOS transistors each including a contact plug PG3 which extends through the oxide film layer 2 and has one end connected to a source of the source/drain active layer 5, for example. The contact plug PG3 is formed in the oxide film layer 2 as follows. An opening is formed in a portion of the oxide film layer 2 by performing known techniques of photolithography or etching on the oxide film layer 2 from one of opposite surfaces thereof which is closer to the supporting substrate 1, and a metal film is buried in the opening. Then, the other end of the contact plug PG3 is connected to the metal film MT1.

Given the foregoing structure according to the fourth preferred embodiment, it is possible to keep a potential of the source/drain active layer 5 of the MOS transistor constant by applying a power-source potential Vdd to the metal film MT1, for example. Also, by forming the metal film MT1 so as to completely cover the surface of the supporting substrate 1, it is possible to reduce a resistance of the metal film MT1, thereby to keep a potential of the source/drain active layer 5 constant, while reducing power consumption.

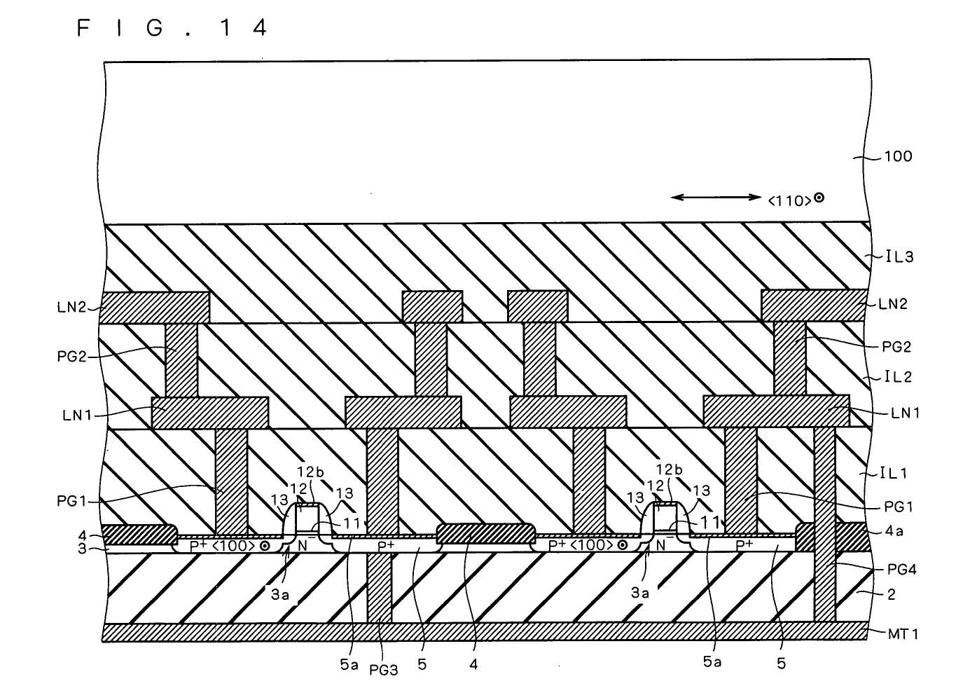

It is additionally noted that the foregoing features of the fourth preferred embodiment can be applied also to the semiconductor device according to the second preferred embodiment, of course. FIG. 13 illustrates a structure of a semiconductor device resulting from applying the features of the fourth preferred embodiment to the semiconductor device according to the second preferred embodiment. In this structure, as the supporting substrate 1 is completely removed and the oxide film layer 2 serves as a bottom of the entire structure, the metal film MT1 is formed on one of the opposite surfaces of the oxide film layer 2 which is farther from the SOI layer 3. The structure illustrated in FIG. 13 is different from the structure illustrated in FIG. 12 only in the foregoing respect, and is identical to the structure illustrated in FIG. 12 in the other respects including formation of the contact plug PG3.

As an alternative to the contact plug PG3 which is connected directly to the source/drain active layer 5, a contact plug which is not connected directly to the source/drain active layer 5, but is connected to the source/drain active layer 5 through an interconnect or the like so as to establish electrical connection between the source/drain active layer 5 and the metal film MT1, may be employed. A contact plug PG4 illustrated in FIG. 14 is one example of such alternative contact plug, which extends through the oxide film layer 2, the isolation region 4a and the first interlayer insulating film IL1, to be connected to the second-level interconnect LN1. It is noted that, in the structure employing the contact plug PG4, the isolation region 4a functions to provide complete isolation, not partial isolation.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
an SOI substrate including a supporting substrate, an oxide film layer and an SOI (Semiconductor-On-Insulator) layer which are sequentially deposited; and
a MIS (Metal Insulator Semiconductor) transistor including a gate insulating film formed on said SOI layer, a gate electrode formed on said gate insulating film and a source/drain active layer formed in said SOI layer so as to be adjacent to a portion under said gate electrode,
wherein at least a portion of said supporting substrate which is located under said MIS transistor is removed, to form a hollow portion.

2. The semiconductor device according to claim 1,
wherein said hollow portion is surrounded by four end faces of said supporting substrate, each of said four end faces being exposed in said hollow portion and being a (111) plane.

3. A semiconductor device comprising:
an SOI substrate including an oxide film layer serving as a bottom of said semiconductor device and an SOI (Semiconductor-On-Insulator) layer which are sequentially deposited;
a MIS (Metal Insulator Semiconductor) transistor including a gate insulating film formed on said SOI layer, a gate electrode formed on said gate insulating film and a source/drain active layer formed in said SOI layer so as to be adjacent to a portion under said gate electrode;
an interlayer insulating film covering said MIS transistor; and
a supporting substrate bonded to said interlayer insulating film.

4. The semiconductor device according to claim 1, further comprising
a metal film covering a surface of said supporting substrate including an end face exposed in said hollow portion, and a portion of said oxide film layer which is exposed in said hollow portion.

5. The semiconductor device according to claim 4, further comprising
a contact plug extending through said oxide film layer and electrically connecting said source/drain active layer of said MIS transistor and said metal film to each other.

6. The semiconductor device according to claim 1,
wherein said supporting substrate and said SOI layer have crystal directions different from each other.

7. The semiconductor device according to claim 3, further comprising
a metal film covering a surface of said oxide film layer.

8. The semiconductor device according to claim 7, further comprising
a contact plug extending through said oxide film layer and electrically connecting said source/drain active layer of said MIS transistor and said metal film to each other.

9. The semiconductor device according to claim 3,
wherein said supporting substrate and said SOI layer have crystal directions different from each other.
